(19) United States
(12) Patent Application Publication
(10) Pub. No.: US 2025/0336681 A1
(43) Pub. Date: Oct. 30, 2025

(54) ETCHING METHOD AND ETCHING DEVICE

(71) Applicant: ULVAC, INC., Chigasaki-shi (JP)

(72) Inventors: Atsuaki Hashimoto, Chigasaki-shi (JP); Kazuhiko Tonari, Chigasaki-shi (JP); Youhei Ono, Chigasaki-shi (JP); Youhei Sata, Chigasaki-shi (JP); Kentaro Kawai, Chigasaki-shi (JP)

(21) Appl. No.: 19/184,945

(22) Filed: Apr. 21, 2025

(30) Foreign Application Priority Data
Apr. 24, 2024 (JP) 2024-070613

(51) Int. Cl. H01L 21/311; H01J 37/32

(52) U.S. Cl. CPC H01L 21/31116; H01J 37/32449; H01J 2237/3346

(57) ABSTRACT

A method for selectively etching a silicon nitride film can include supplying a hydrogen fluoride gas to an etching subject while heating the etching subject so that a temperature of the etching subject is maintained at a predetermined temperature included in a range of a first temperature to a second temperature, inclusive. The method can include supplying active radicals generated from a radical generation gas to the etching subject while heating the etching subject so that the temperature of the etching subject after being supplied with the hydrogen fluoride gas is maintained at the predetermined temperature.

### CROSS-REFERENCE TO RELATED APPLICATIONS

This application is based upon and claims the benefit of priority from Japanese Patent Application No. 2024-070613, filed on Apr. 24, 2024, the entire contents of which are incorporated herein by reference.

### TECHNICAL FIELD

The following description relates to an etching method and an etching device.

### BACKGROUND

An example of a method for selectively etching a silicon nitride film of a wafer, in which the silicon nitride film and a silicon oxide film are arranged adjacent to each other, includes a step of supplying hydrogen fluoride gas to a processing compartment, in which the wafer is accommodated, and a step of supplying radicals of an inert gas to the processing compartment. In the step of supplying hydrogen fluoride gas and the step of supplying inert gas radicals, the temperature of the wafer is maintained at a relatively low temperature. In the etching method, first, the hydrogen fluoride gas is supplied to the wafer so that hydrogen fluoride is adsorbed on the surface of the silicon nitride film. Next, the inert gas radicals are supplied to the wafer so that the wafer receives energy that is greater than or equal to an activation energy for etching reaction of hydrogen fluoride and silicon nitride.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In the above etching method, the temperature of the wafer is maintained at a relatively low temperature over a period during which etching of the silicon nitride film progresses. Therefore, ammonia, which is produced by the etching reaction of hydrogen fluoride and silicon nitride, does not easily desorb from the surface of the wafer. Accordingly, the silicon oxide film included in the wafer together with the silicon nitride film is supplied with hydrogen fluoride and ammonia and, in turn, etching of the silicon oxide film progresses. Such a problem is not limited to a wafer that includes a silicon oxide film together with a silicon nitride film, and also occurs in a wafer that includes a polysilicon film together with a silicon nitride film.

In one general aspect, a method is for selectively etching a silicon nitride film of an etching subject that includes the silicon nitride film and either a silicon oxide film or a polysilicon film. The method includes supplying a hydrogen fluoride gas to the etching subject while heating the etching subject so that a temperature of the etching subject is maintained at a predetermined temperature included in a range of a first temperature to a second temperature, inclusive; and supplying active radicals generated from a radical generation gas to the etching subject while heating the etching subject so that the temperature of the etching subject after being supplied with the hydrogen fluoride gas is maintained at the predetermined temperature.

In another general aspect, an etching device includes a vacuum container, a heater, a hydrogen fluoride gas supplier, a radical supplier, and a controller. The vacuum container defines a processing space configured to accommodate an etching subject. The etching subject includes a silicon nitride film and either a silicon oxide film or a polysilicon film. The heater is configured to heat the etching subject. The hydrogen fluoride gas supplier supplies a hydrogen fluoride gas into the processing space. The radical supplier supplies active radicals generated from a gas containing oxygen atoms into the processing space. The controller controls operations of the heater, the hydrogen fluoride gas supplier, and the radical supplier. The controller is configured to, while causing the heater to heat the etching subject so that the etching subject is maintained at a predetermined temperature included in a range of a first temperature to a second temperature, inclusive, cause the hydrogen fluoride gas supplier to supply the hydrogen fluoride gas and then cause the radical supplier to supply the active radicals.

Other features and aspects will be apparent from the following detailed description, the drawings, and the claims.

### BRIEF DESCRIPTION OF THE DRAWINGS

FIG. 1 is an example of a schematic diagram showing the configuration of an etching device.

FIG. 2 is an example of a schematic diagram showing the configuration of an etching chamber of the etching device shown in FIG. 1.

FIG. 3 is an example of a timing diagram illustrating operations of suppliers of the etching device.

FIG. 4 is an example of a diagram illustrating a step of the etching method.

FIG. 5 is an example of a diagram illustrating a step of the etching method.

FIG. 6 is an example of a diagram illustrating a step of the etching method.

FIG. 7 is an example of a diagram illustrating a step of the etching method.

FIG. 8 is an example of a graph illustrating a selection ratio of a silicon nitride film to a silicon oxide film in experimental examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

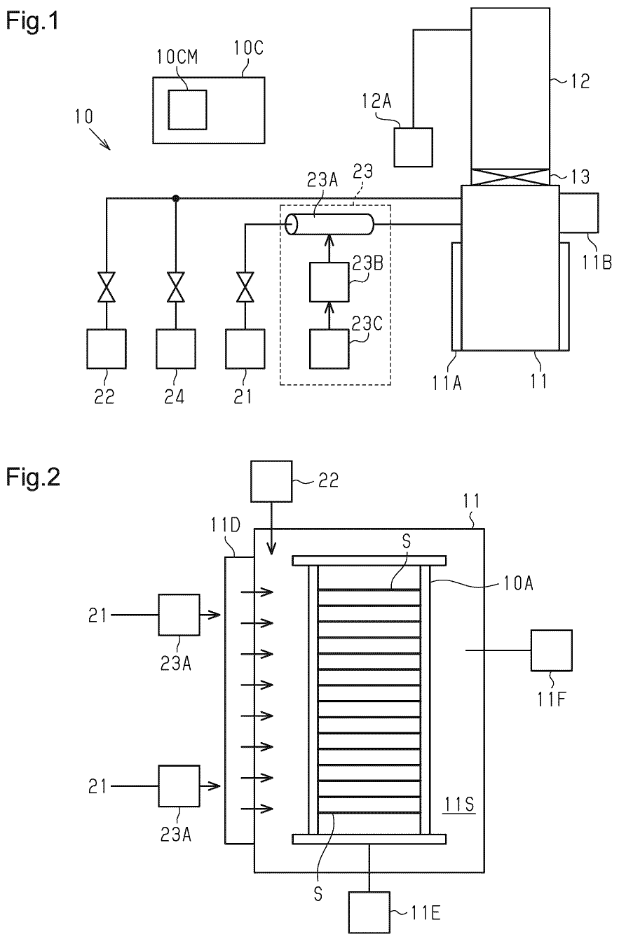

An embodiment of an etching method and an etching device will now be described with reference to FIGS. 1 to 8.

### Etching Device

The etching device will be described with reference to FIG. 1.

As shown in FIG. 1, an etching device 10 includes an etching chamber 11, a load lock chamber 12, and a gate valve 13. The etching device 10 includes an oxygen-containing gas supplier 21, a hydrogen fluoride (HF) gas supplier 22, a plasma supplier 23, and an inert gas supplier 24. The etching device 10 includes a controller 10C.

The etching chamber 11 is an example of a vacuum container. The etching chamber 11 defines a processing space 11S (refer to FIG. 2) in which a substrate S (refer to FIG. 2) is accommodated. The substrate S is an example of an etching subject. The substrate S includes a silicon nitride film and either a silicon oxide film or a polysilicon film. The etching chamber 11 performs etching of the silicon nitride film in the processing space 11S. The load lock chamber 12 loads a pre-etching substrate S into the etching chamber 11 from the outside of the etching device 10. The load lock chamber 12 unloads a post-etching substrate S out of the etching chamber 11 to the outside of the etching device 10.

The gate valve 13 is arranged between the etching chamber 11 and the load lock chamber 12. The gate valve 13 opens and connects the etching chamber 11 to the load lock chamber 12. The gate valve 13 closes and disconnects the etching chamber 11 from the load lock chamber 12.

The load lock chamber 12 is connected to a coolant gas supplier 12A. The coolant gas supplier 12A supplies a coolant gas to the load lock chamber 12. The coolant gas is an inert gas used to cool etched substrates S.

The etching chamber 11 includes a heater 11A and a gas discharger 11B. The heater 11A heats the etching chamber 11 so as to heat the substrate S in the processing space 11S. The gas discharger 11B reduces the pressure of the etching chamber 11 to a predetermined pressure.

The etching chamber 11 is connected to the HF gas supplier 22 and the plasma supplier 23. The HF gas supplier 22 supplies HF gas to the processing space 11S. The HF gas supplier 22 is configured to supply the HF gas to the processing space 11S at a predetermined flow rate. The HF gas supplier 22 is, for example, a mass flow controller.

The plasma supplier 23 supplies plasma to the processing space 11S so as to supply active radicals contained in the plasma into the processing space 11S. The oxygen-containing gas supplier 21 and the plasma supplier 23 form an example of a radical supplier.

The plasma supplier 23 includes a discharge tube 23A, a waveguide 23B, and a microwave irradiator 23C. The microwave irradiator 23C emits microwaves through the waveguide 23B to the discharge tube 23A. The discharge tube 23A is connected to the oxygen-containing gas supplier 21. The discharge tube 23A includes an inner surface formed from an inorganic oxide. The inorganic oxide forming the inner surface of the discharge tube 23A may be a silicon oxide or an aluminum oxide. The discharge tube 23A may be, for example, a quartz tube.

The oxygen-containing gas supplier 21 supplies a gas containing oxygen atoms to the discharge tube 23A. The oxygen-containing gas supplier 21 is configured to supply the gas containing oxygen atoms to the discharge tube 23A at a predetermined flow rate. The oxygen-containing gas supplier 21 is, for example, a mass flow controller.

The gas containing oxygen atoms is an example of a radical generation gas. The gas containing oxygen atoms may be at least one selected from a group consisting of oxygen gas, a nitrogen oxide (NₓO_{y}) gas, and a mixture gas of oxygen gas and hydrogen gas. The nitrogen oxide gas may be, for example, any of nitrogen monoxide (NO) gas, nitrogen dioxide (NO₂) gas, dinitrogen monoxide (N₂O) gas, dinitrogen trioxide (N₂O₃) gas, and dinitrogen pentoxide (N₂O₅) gas.

The plasma supplier 23 irradiates the oxygen-containing gas in the discharge tube 23A with microwaves so as to generate plasma inside the discharge tube 23A. The plasma includes oxygen-containing radicals.

The inert gas supplier 24 supplies an inert gas to the processing space 11S. The inert gas supplier 24 is configured to supply the inert gas to the processing space 11S at a predetermined flow rate. The inert gas supplier 24 is, for example, a mass flow controller. The inert gas may be, for example, nitrogen (N₂) gas or argon (Ar) gas. The inert gas supplier 24 may supply the inert gas into the processing space 11S using the same pipe as the HF gas supplier 22. Alternatively, the inert gas supplier 24 may supply the inert gas into the processing space 11S using a separate pipe.

The controller 10C includes memory 10CM. The memory 10CM stores processing conditions for etching a silicon nitride film. The processing conditions include pressure of the etching chamber 11, temperature of the substrate S, flow rates of different types of gases, and output of the microwave irradiator 23C. The controller 10C controls operations of the heater 11A, the gas discharger 11B, the oxygen-containing gas supplier 21, the HF gas supplier 22, the plasma supplier 23, and the inert gas supplier 24 so that etching conditions conform to the processing conditions.

While the controller 10C is causing the heater 11A to heat the substrate S so that the substrate S is maintained at a predetermined temperature included in a range of a first temperature to a second temperature, inclusive, the controller 10C causes the HF gas supplier 22 to supply the HF gas and then causes the radical supplier to supply the active radicals.

### Etching Chamber

As shown in FIG. 2, the etching chamber 11 accommodates a support 10A. The support 10A is configured to support a plurality of substrates S. The substrates S supported by the support 10A are stacked with a gap provided between adjacent ones of the substrates S. The substrates S each include a silicon nitride film and either a silicon oxide film or a polysilicon film. An example of the substrate S is disc-shaped.

The etching chamber 11 includes a shower head 11D. The shower head 11D is connected to the discharge tube 23A. Any number of discharge tubes 23A may be connected to the shower head 11D. FIG. 2 shows an example in which two discharge tubes 23A are connected to the shower head 11D. The shower head 11D has a plurality of supplying ports. The supplying ports of the shower head 11D are arranged side by side in the direction in which the substrates S are stacked. The plasma delivered from the discharge tubes 23A is ejected from the supplying ports of the shower head 11D toward the substrates S.

The etching chamber 11 includes a rotor 11E. The rotor 11E rotates the support 10A in a circumferential direction of the substrates S. The rotor 11E disperses the plasma ejected from the shower head 11D toward the substrates S and the HF gas delivered from the HF gas supplier 22 toward the substrates S in a circular direction of the substrates S.

The etching chamber 11 includes a thermometer 11F. The thermometer 11F measures the temperature inside the etching chamber 11 as the temperature of the substrate S. The thermometer 11F is connected to the controller 10C. The temperature measured by the thermometer 11F is input to the controller 10C. The controller 10C controls operation of the heater 11A based on the measurement result by the thermometer 11F.

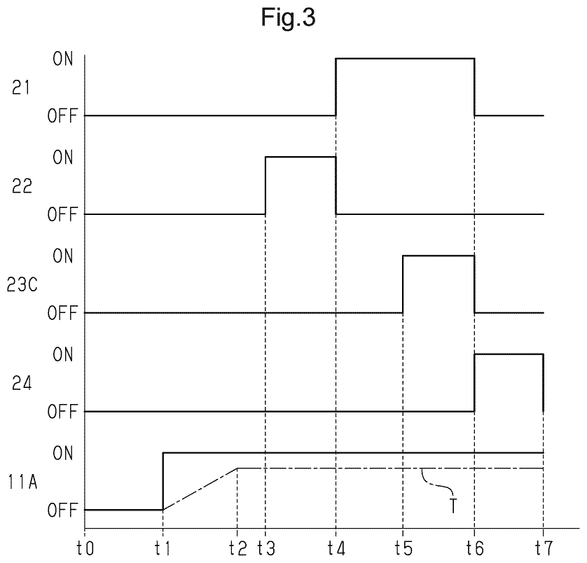

FIG. 3 shows an example of a mode in which the controller 10C operates the heater 11A, the oxygen-containing gas supplier 21, the HF gas supplier 22, the microwave irradiator 23C, and the inert gas supplier 24. In FIG. 3, a state in which the heater 11A is not heating the etching chamber 11 is indicated as “OFF”, and a state in which the heater 11A is heating the etching chamber 11 is indicated as “ON”. Also, a state in which the microwave irradiator 23C is not emitting microwaves is indicated as “OFF”, and a state in which the microwave irradiator 23C is emitting microwaves is indicated as “ON”.

Furthermore, states in which the gas suppliers 21, 22, and 24 are not delivering gases are each indicated as “OFF”, and states in which the gas suppliers 21, 22, and 24 are delivering gases are each indicated as “ON”.

As shown in FIG. 3, when etching the substrate S in the etching chamber 11, the controller 10C causes the heater 11A to start heating the etching chamber 11 at time t1. Accordingly, temperature T of the substrate S starts to rise. At time t2, the temperature T of the substrate S reaches the predetermined temperature included in a range of the first temperature to the second temperature, inclusive.

Thereafter, at time t3, the controller 10C causes the HF gas supplier 22 to start supplying the HF gas. Then, at time t4, the controller 10C causes the HF gas supplier 22 to stop supplying the HF gas and causes the oxygen-containing gas supplier 21 to start supplying the oxygen-containing gas. At time t5, the controller 10C causes the microwave irradiator 23C to start emitting microwaves.

Subsequently, at time t6, the controller 10C causes the oxygen-containing gas supplier 21 to stop supplying the oxygen-containing gas, causes the microwave irradiator 23C to stop emitting microwaves, and causes the inert gas supplier 24 to start supplying the inert gas. At time t7, the controller causes the inert gas supplier 24 to stop supplying the inert gas.

As described above, during the processing executed by the controller 10C in the etching chamber 11, a step of heating the substrate S is initiated at time t1, and the substrate S is continuously heated until etching of the substrate S is ended. Further, during the processing executed by the controller 10C in the etching chamber 11, the process from time t3 to time t4 corresponds to a step of supplying HF gas, and the process from time t4 to time t6 corresponds to a step of supplying an oxygen-containing gas. Moreover, during the processing executed by the controller 10C in the etching chamber 11, the process from time t5 to time t6 corresponds to a step of supplying active radicals, and the process from time to to time t7 corresponds to a step of supplying an inert gas.

That is, the process from time t3 to time t7 defines a single cycle. The controller 10C executes such a cycle multiple times in the etching chamber 11 until an etching amount of the silicon nitride film in the substrate S reaches a predetermined amount. The controller 10C may execute the cycle a predetermined number of times in the etching chamber 11.

### Etching Method

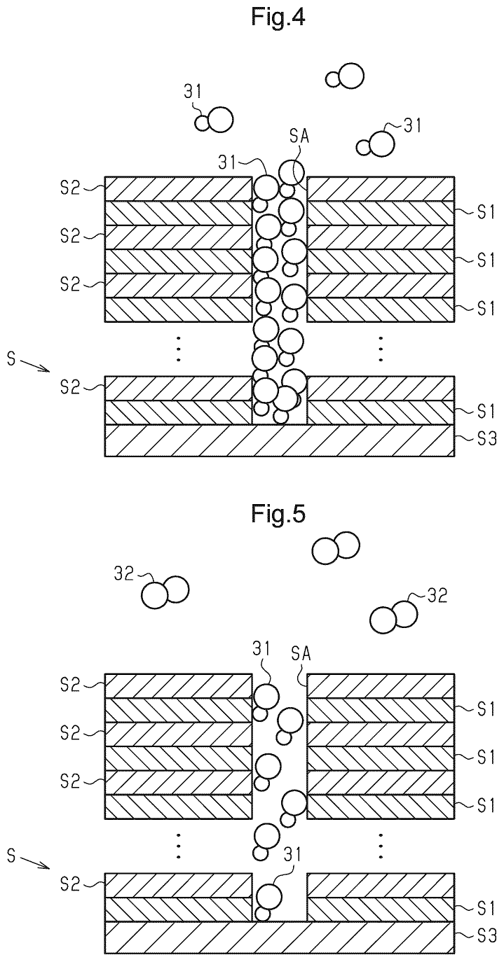

The etching method will now be described with reference to FIGS. 4 to 7.

The etching method according to the present disclosure is a method for selectively etching a silicon nitride film of an etching subject that includes the silicon nitride film and either a silicon oxide film or a polysilicon film. The etching method includes supplying HF gas to the etching subject, and supplying active radicals to the etching subject after supplying HF gas to the etching subject. The supplying HF gas to the etching subject includes supplying hydrogen fluoride gas to the etching subject while heating the etching subject so that the temperature of the etching subject is maintained at the predetermined temperature included in a range of the first temperature to the second temperature, inclusive. The supplying active radicals to the etching subject includes supplying active radicals generated from a radical generation gas to the etching subject while heating the etching subject so that the temperature of the etching subject after being supplied with the HF gas is maintained at the predetermined temperature.

With the etching method according to the present disclosure, the HF gas and the active radicals are supplied to the etching subject that is heated to the predetermined temperature. Therefore, the HF is evenly adsorbed in a depth-wise direction of the etching subject. Also, the HF reacts with the active radicals in the etching subject that is heated to the predetermined temperature. Therefore, ammonia (NH₃), which is a by-product of etching of the silicon nitride film, readily desorbs from the etching subject. This avoids a situation in which the silicon oxide film or the polysilicon film is etched by an etchant produced from HF and NH₃. As a result, a selection ratio of the silicon nitride film to the silicon oxide film or the polysilicon film is increased. The etching method will now be described in more detail with reference to FIGS. 4 to 7.

As shown in FIG. 4, an example of the substrate S may include a multilayer film structure. The silicon nitride film corresponds to a first silicon film S1. The silicon oxide film or the polysilicon film corresponds to a second silicon film S2. The substrate S, which is an example of the etching subject, includes a plurality of first silicon films S1 and a plurality of second silicon films S2. The first silicon films S1 and the second silicon films S2 are alternately stacked in the substrate S. The substrate S includes a support substrate S3. The multilayer film structure, which includes the first silicon films S1 and the second silicon films S2, is formed on the support substrate S3.

The substrate S includes a hole SA extending in a thickness-wise direction. The hole SA extends through two or more layers of the first silicon film S1 and two or more layers of second silicon film S2. Although only one hole SA is shown in FIGS. 4 to 7 for illustrative purposes, the substrate S includes a plurality of holes SA. The substrate S may be, for example, a substrate for a three-dimensional (3D) NAND device.

In the etching method, first, HF gas is supplied to the substrate S that is heated to the first temperature. Accordingly, the HF gas supplied to the substrate S also reaches the hole SA. In the etching method according to the present disclosure, the substrate S is being heated when the substrate S is supplied with HF 31, and thus the HF 31 readily reaches the inside of the hole SA. This facilitates etching of the first silicon films S1, which are silicon nitride films defining the hole SA.

Since the HF 31 has a relatively high adsorptive property with the substrate S, a greater amount of HF 31 is likely to be adsorbed near the opening of the hole SA than at the bottom of the hole SA. In this respect, the substrate S is heated to the first temperature or higher so that the HF 31 supplied to the substrate S is not easily consumed (i.e., adsorbed) near the opening of the hole SA. As a result, the HF 31 readily reaches the bottom of the hole SA.

The first temperature may be 80° C., and the second temperature may be 400° C. When the first temperature is 80° C., the HF 31 will be evenly adsorbed in the depth-wise direction of the substrate S. Specifically, energy is applied to the HF 31 adsorbed on the surface of the substrate S, and thus the HF 31 will not be excessively adsorbed on the substrate S near the opening of the hole SA. Further, when the second temperature is 400° C., the temperature of the substrate S will not be excessively high, and thus the HF 31 will be readily adsorbed on the substrate S. From the perspective of the even adsorption of the HF 31 in the substrate S, the first temperature may be 100° C., 120° C., or 140° C.

In the step of supplying the HF gas to the substrate S, the pressure in the processing space 11S, in which the substrate S is accommodated and to which the HF gas is supplied, may be 500 Pa or higher. When the pressure in the processing space 11S is 500 Pa or higher, the HF 31 is readily adsorbed on the substrate S. This facilitates etching of the first silicon films S1.

As shown in FIG. 5, after the substrate S is supplied with the HF gas, the HF gas is switched to the radical generation gas. As discussed above, the radical generation gas may be a gas containing oxygen atoms. This allows for generation of active radicals that are resistant to deactivation and act as an oxidation source. As described above, the gas containing oxygen atoms may be at least one selected from a group consisting of O₂ gas, NₓO_{y} gas, and a mixture gas of O₂ gas and H₂ gas.

The gas containing oxygen atoms may be, for example, O₂ gas. Since O₂ 32 has a higher affinity for the second silicon films S2 than the HF 31, when the O₂ gas is supplied to the substrate S, the O₂ 32 replaces the HF 31 adsorbed on the second silicon films S2 defining the hole SA. However, the O₂ 32 has a relatively low adsorptive property, such that the O₂ 32 is not likely to remain on the second silicon films S2.

When the radical generation gas is supplied to the substrate S between supplying the HF gas to the substrate S and supplying the active radicals to the substrate S, the flow of a fluid generated from the radical generation gas may remove at least some of unnecessary HF 31 located on the substrate S.

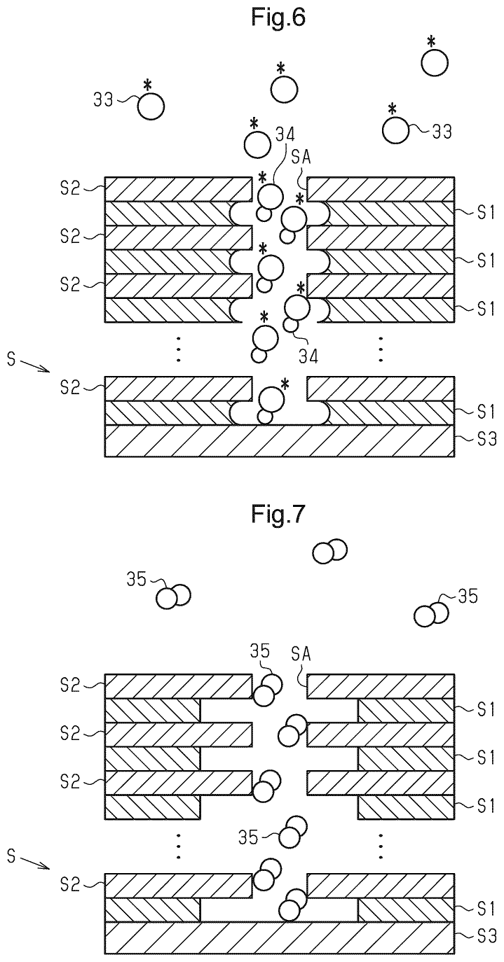

As shown in FIG. 6, the substrate S is supplied with active radicals 33 generated from the radical generation gas. In turn, an etchant 34 for etching the first silicon films S1 is produced from the active radicals 33 and the HF 31 adsorbed on the first silicon films S1 defining the hole SA. In this manner, the surface reaction between the HF 31 and the active radicals 33 progresses on the substrate S, thereby etching the first silicon films S1. The etching of the first silicon films S1 progresses in a direction orthogonal to the depth-wise direction of the hole SA.

When the radical generation gas is O₂ gas, the active radicals 33 are particularly resistant to deactivation, and thus the active radicals 33 are readily supplied to the inside of the hole SA. This facilitates etching of the first silicon films S1 inside the hole SA, including at positions near the bottom of the hole SA. Furthermore, when the second silicon films S2 are silicon oxide films and the active radicals 33 are generated from a gas containing oxygen atoms, the active radicals 33 may repair the surfaces of the second silicon films S2. This further improves the selection ratio of the first silicon film S1 to the second silicon film S2.

As shown in FIG. 7, after the substrate S is supplied with the active radicals 33, the active radicals 33 are switched to the inert gas. As described above, the inert gas may be, for example, N₂ gas.

As described above, in the etching method, a single cycle includes supplying the HF gas to the substrate S, and supplying the active radicals 33 to the substrate S. The etching method may include repeating such a cycle. Each cycle includes supplying the inert gas to the substrate S after supplying the active radicals 33 to the substrate S.

This avoids a situation in which the active radicals supplied to the etching subject in the “n”th cycle exist near the substrate S at the beginning of the “n+1”th cycle. As a result, when the substrate S is supplied with the HF gas in the “n+1”th cycle, the substrate S will not be etched at portions that do not correspond to the first silicon films S1.

When the substrate S is supplied with nitrogen gas, nitrogen 35 reaches the hole SA and replaces the HF31, the active radicals 33, and the etchant 34 remaining in the hole SA.

When repeating the etching cycle multiple times on the substrate S, the temperature of the substrate S is maintained at a predetermined value included in a range of the first temperature to the second temperature, inclusive, over a period from the first cycle to the end of the final cycle.

### EXPERIMENTAL EXAMPLES

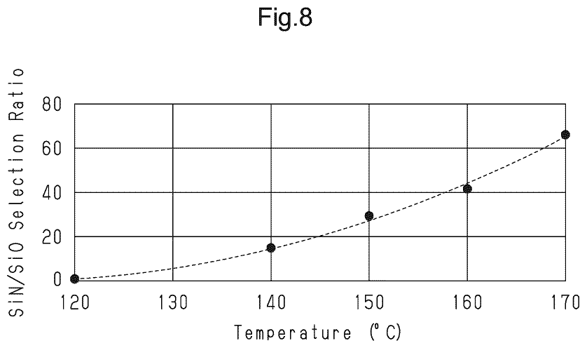

Experimental examples will now be described with reference to FIG. 8.

### Experimental Example 1

A first silicon substrate on which a silicon nitride film is formed, and a second silicon substrate on which a silicon oxide film is formed were prepared. Then, the HF gas supplying step, the oxygen gas supplying step, the oxygen radical supplying step, and the nitrogen gas supplying step were performed under the following conditions. Specifically, the cycle including the above four steps were repeated 400 times to etch the first silicon substrate and the second silicon substrate. In this case, the temperature of each substrate was set to 120° C.

### HF Gas Supplying Step

HF gas flow rate: 5000 sccm
Processing space pressure: 3500 Pa
Gas supply duration: 30 seconds

### Oxygen Gas Supplying Step

Oxygen gas flow Rate: 5500 sccm
Processing space pressure: 500 Pa
Gas supply duration: 6 seconds

### Active Radical Supplying Step

Oxygen gas flow rate: 5500 sccm
Processing space pressure: 500 Pa
Gas supply duration: 1 second
Microwave irradiation intensity: 2800 W

### Inert Gas Supplying Step

Nitrogen gas flow rate: 60000 sccm
Processing space pressure: 60 Pa
Gas supply duration: 6 seconds

### Experimental Example 2

The substrates were etched in the same manner as in Experimental Example 1, except that the temperature of the substrates was set to 140° C.

### Experimental Example 3

The substrates were etched in the same manner as in Experimental Example 1, except that the temperature of the substrates was set to 150° C.

### Experimental Example 4

The substrates were etched in the same manner as in Experimental Example 1, except that the temperature of the substrates was set to 160° C.

### Experimental Example 5

The substrates were etched in the same manner as in Experimental Example 1, except that the temperature of the substrates was set to 170° C.

### Evaluation Method

In each experimental example, the thickness of the silicon nitride film of the first substrate before etching and the thickness of the silicon oxide film of the second substrate before etching were measured using an ellipsometer (RE-3500, manufactured by SCREEN Holdings Co., Ltd.). Also, the thickness of the silicon nitride film of the first substrate after etching and the thickness of the silicon oxide film of the second substrate after etching were measured using the ellipsometer (same as above).

Then, an etching amount of the silicon nitride film was calculated by subtracting the thickness of the silicon nitride film after etching from the thickness of the silicon nitride film before etching. Also, an etching amount of the silicon oxide film was calculated by subtracting the thickness of the silicon oxide film after etching from the thickness of the silicon oxide film before etching.

In each experimental example, the selection ratio of the silicon nitride film to the silicon oxide film was calculated by dividing the etching amount of the silicon nitride film by the etching amount of the silicon oxide film.

### Evaluation Results

As shown in FIG. 8, the selection ratio of Experimental Example 1 was 0, the selection ratio of Experimental Example 2 was 18, the selection ratio of Experimental Example 3 was 25, the selection ratio of Experimental Example 4 was 42, and the selection ratio of Experimental Example 5 was 63. This indicates that when the temperature of the substrate is 140° C. or higher, the selection ratio of the silicon nitride film to the silicon oxide film is significantly improved.

As described above, the etching method and the etching device in accordance with the embodiment have the following advantages.
(1) The HF gas and the active radicals are supplied to the substrate S that is heated to the predetermined temperature. Therefore, the HF 31 is evenly adsorbed on the substrate S. Also, the HF 31 reacts with the active radicals 33 in the substrate S that is heated to the predetermined temperature. Therefore, NH₃, which is a by-product of etching of the first silicon films S1, readily desorbs from the substrate S. This avoids a situation in which the second silicon films S2 are etched by an etchant produced from the HF 31 and NH₃. As a result, the selection ratio of the first silicon film S1 to the second silicon film S2 is increased.
(2) When the first temperature is 80° C., the HF will be evenly adsorbed on the substrate S at a relatively high reliability. Further, when the second temperature is 400° C., the temperature of the substrate S will not be excessively high, and thus the HF 31 will be readily adsorbed on the substrate S.
(3) When the pressure in the processing space 11S is 500 Pa or higher, the HF 31 is readily adsorbed on the substrate S. This facilitates etching of the first silicon films S1.
(4) The radial generation gas containing oxygen allows for generation of the active radicals 33 that are resistant to deactivation and act as an oxidation source.
(5) When the etching method includes the radical generation gas supplying step (in the example shown in FIG. 3, the period from time t4 to time t5) prior to supplying the active radicals 33, the flow of a fluid generated from the radical generation gas may remove at least some of unnecessary HF located on the substrate S.
(6) When the etching method includes the inert gas supplying step, the active radicals 33 supplied to the substrate S in the “n”th cycle will not exist near the substrate S at the beginning of the “n+1”th cycle. As a result, when the substrate S is supplied with the HF gas in the “n+1”th cycle, the substrate S will not be etched at portions that do not correspond to the first silicon films S1.
(7) Even when the substrate S includes the hole SA, the substrate S is heated so that the HF is readily supplied to the inside of the hole SA. This facilitates etching of the first silicon films S1 defining the hole SA.

The above embodiment may be modified as described below.

### Etching Method

A single cycle of the etching method does not have to include at least one of the radical generation gas supplying step and the inert gas supplying step. That is, a single cycle may include at least the HF gas supplying step and the active radical supplying step. Even in this case, an advantage equivalent to advantage (1) is obtained.

### Radical Generation Gas

The radical generation gas does not have to contain oxygen atoms. The radical generation gas may be, for example, an inert gas. The inert gas may be, for example, Ar gas.

### Substrate

The first silicon films S1 and the second silicon films S2 do not have to be alternately stacked, and the substrate S may include the first silicon film S1 and the second silicon film S2 at a same surface level. Even in this case, an advantage equivalent to advantage (1) is obtained.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A method for selectively etching a silicon nitride film of an etching subject that includes the silicon nitride film and either a silicon oxide film or a polysilicon film, the method comprising:
supplying a hydrogen fluoride gas to the etching subject while heating the etching subject so that a temperature of the etching subject is maintained at a predetermined temperature included in a range of a first temperature to a second temperature, inclusive; and
supplying active radicals generated from a radical generation gas to the etching subject while heating the etching subject so that the temperature of the etching subject after being supplied with the hydrogen fluoride gas is maintained at the predetermined temperature.

2. The method according to claim 1, wherein the first temperature is 80° C., and wherein the second temperature is 400° C.

3. The method according to claim 1, wherein the supplying the hydrogen fluoride gas to the etching subject includes supplying the hydrogen fluoride gas to the etching subject when a pressure in a processing space, in which the etching subject is accommodated and to which the hydrogen fluoride gas is supplied, is 500 Pa or higher.

4. The method according to claim 1, wherein the radical generation gas includes a gas containing oxygen atoms.

5. The method according to claim 4, wherein the gas containing oxygen atoms includes at least one of an oxygen gas, a nitrogen oxide gas, or a mixture gas of an oxygen gas and a hydrogen gas.

6. The method according to claim 1, further comprising:
supplying the radical generation gas to the etching subject between the supplying the hydrogen fluoride gas to the etching subject and the supplying the active radicals to the etching subject.

7. The method according to claim 1, wherein the method includes repeating a cycle multiple times, and wherein the cycle includes:
the supplying hydrogen fluoride gas to the etching subject;
the supplying the active radicals to the etching subject; and
supplying an inert gas to the etching subject after the supplying the active radicals to the etching subject.

8. The method according to claim 1, wherein the etching subject includes two or more layers of first silicon films and two or more layers of second silicon films, the first silicon films and the second silicon films alternately stacked one by one, wherein each of the first silicon films corresponds to the silicon nitride film, wherein each of the second silicon films corresponds to the silicon oxide film or the polysilicon film, wherein the etching subject includes a hole extending in a thickness-wise direction, and wherein the hole extends through the two or more layers of the first silicon films and the two or more layers of the second silicon films.

9. An etching device, comprising:
a vacuum container defining a processing space configured to accommodate an etching subject, the etching subject including a silicon nitride film and either a silicon oxide film or a polysilicon film;
a heater configured to heat the etching subject;
a hydrogen fluoride gas supplier configured to supply a hydrogen fluoride gas into the processing space;
a radical supplier configured to supply active radicals generated from a gas containing oxygen atoms into the processing space; and
a controller configured to control operations of the heater, the hydrogen fluoride gas supplier, and the radical supplier, wherein, the controller is configured to, while causing the heater to heat the etching subject so that the etching subject is maintained at a predetermined temperature included in a range of a first temperature to a second temperature, inclusive, cause the hydrogen fluoride gas supplier to supply the hydrogen fluoride gas and then cause the radical supplier to supply the active radicals.
